(19) United States
(12) Patent Application Publication
(10) Pub. No.: US 2026/0185267 A1
(43) Pub. Date: Jul. 2, 2026

(54) ALIGNED GROWTH OF LOW-SYMMETRY TRANSITION METAL DICHALCOGENIDES ON HIGH-SYMMETRY SURFACE

(71) Applicant: CITY UNIVERSITY OF HONG KONG, Kowloon (HK)

(72) Inventors: Thuc Hue LY, Kowloon (HK); Honglin CHEN, Kowloon (HK); Lingli HUANG, Kowloon (HK)

(21) Appl. No.: 19/279,993

(22) Filed: Jul. 24, 2025

Related U.S. Application Data
(60) Provisional application No. 63/739,009, filed on Dec. 26, 2024.

(51) Int. Cl. C30B 29/46; C22F 1/14; C30B 25/18; C30B 33/10

(52) U.S. Cl. CPC C30B 29/46; C22F 1/14; C30B 25/18; C30B 33/10

(57) ABSTRACT

A method of growing low-symmetry two-dimensional (2D) transition metal dichalcogenide (TMD) on a high-symmetry surface includes: (a) placing precursors of a low-symmetry 2D TMD and a gold foil with Au (111) domain in a chamber having a first zone and a second zone, in which the precursors of the low-symmetry 2D TMD are placed in the first zone while the gold foil with Au (111) domain is placed in the second zone; (b) respectively raising the temperature in the first and second zones to 250° C. and 950° C. within 30 minutes in the presence of an inert gas; and (c) maintaining the temperature in the second zone at 950° C. for 2-5 minutes to allow aligned growth of the low-symmetry 2D TMD on the gold foil with Au (111) domain thereby forming the film of low-symmetry 2D TMD. The film produced has about 98% of a unidirectional ratio of triangular-shaped 2D TMD.

### CROSS-REFERENCE TO RELATED APPLICATIONS

This application claims priority and the benefit of U.S. Provisional Patent Application No 63/739,009, filed Dec. 26, 2024, the entirety of which is incorporated herein by reference.

### BACKGROUND OF THE INVENTION

### 1. Field of the Invention

The present invention relates to production method of low-symmetry two-dimensional (2D) transition metal dichalcogenide (TMD) film, particularly, methods of growing low-symmetry 2D TMD on a high-symmetry surface thereby forming the desired low-symmetry 2D TMD film.

### 2. Description of Related Art

2D materials have attracted great interests owing to their outstanding electronic, optical properties for developing next generation semiconducting device and large area 2D material preparation is an essential step for future industrial application. Since chemical vapor deposition (CVD) and metal-organic (MO) CVD methods could provide scalable and controllable large size high quality 2D materials compared with other preparation methods (e.g., mechanical exfoliation, liquid exfoliation and etc), it has been widely used and explored to grow wafer-scale 2D materials. To date, two common strategies have been employed to grow wafer-scale single-crystal 2D materials by CVD method. The first strategy involves reducing the nucleation density, e.g., only allowing one nucleus and making it grow into a large single crystal laterally on a substrate. However, strictly restricting one nucleus is challenging, and up to now, only graphene has successfully grown into a wafer-scale single-crystal film from a nucleate site on a Cu—Ni substrate. The second strategy involves achieving seamless stitching of unidirectional single-crystal flake, which allows multiple nucleate sites and has been widely adopted to grow various high-symmetry 2D materials on different substrates, for instance, wafer-scale single-crystal graphene and hexagonal boron nitride (hBN) film have been successfully synthesized on Cu(111) and Cu(110) substrate.

The method of seamless stitching of aligned 2D materials method has shown great potential in realizing wafer-scale single-crystal growth of all kinds of high-symmetry 2D materials. However, there are limited reports on aligned growth and film formation behavior of low-symmetry 2D materials (such as ReX₂, X═S, Se). Rhenium disulfide (ReS₂), a low-symmetry 2D TMDs material, has attracted significant interest due to its in-plane anisotropy, distorted 1T structure, and layer-independent properties. Numerous attempts have been made to prepare atomically thin ReS₂ on various insulating substrates, such as mica, sapphire and glass. However, the resulting ReS₂ films often exhibit diverse orientations and abundant grain boundaries upon merging.

In view of above, there exists in the related art a need for an improved method of producing continuous 2D ReS₂ films formed by highly oriented crystals.

### SUMMARY

Embodiments of the present disclosure relate to a method of producing a film of low-symmetry two-dimensional (2D) transition metal dichalcogenide (TMD). The method includes steps of:
(a) placing precursors of a low-symmetry 2D TMD and a gold foil with Au (111) domain in a chamber having a first zone and a second zone, wherein the precursors of the low-symmetry 2D TMD are placed in the first zone while the gold foil with Au (111) domain is placed in the second zone;
(b) respectively raising the temperature in the first and second zones to 250° C. and 950° C. within 30 minutes in the presence of an inert gas; and
(c) maintaining the temperature in the second zone at 950° C. for 2-5 minutes to allow aligned growth of the low-symmetry 2D TMD on the gold foil with Au (111) domain thereby forming the film of low-symmetry 2D TMD.

According to embodiments of the present disclosure, the gold foil with Au (111) domain in step (a) is produced by a method comprising:
(i) hanging a gold foil on a bar with a portion of the gold foil not in contact with the bar; and
(ii) annealing the gold foil at 1,070° C. for 3 minutes in the presence of an inert gas to transform the portion of the gold foil not in contact with the bar into the gold foil with Au (111) domain;
   wherein, the Au (111) domain is in centimeter-scale.

According to embodiments of the present disclosure, in step (a), the precursors of the low-symmetry 2D TMD are elemental sulfur and ammonium perrhenate (NH₄ReO₄) or elemental selenium (Se) and ammonium perrhenate (NH₄ReO₄).

Examples of the inert gas suitable for use in step (b) and/or step (ii) include, but are not limited to, helium, argon, nitrogen and the like. According to one preferred embodiment of the present disclosure, both step (b) and step (ii) are conducted in the presence of argon.

According to embodiments of the present disclosure, the film of low-symmetry 2D TMD in step (c) is a film of low-symmetry 2D ReS₂ or a film of low-symmetry 2D ReSe₂.

Alternatively or in addition, the present method further includes a step of transferring the film of low-symmetry 2D TMD onto a substrate of silicon dioxide/silicone (SiO₂/Si) or a transmission electron microscopy (TEM) copper grid via a method of wet chemical etching.

According to embodiments of the present disclosure, the method of wet chemical etching includes steps of:
(1) spin-coating a solution of poly methyl methacrylate (PMMA) on to the film of low-symmetry 2D TMD thereby forming a 3-layer composite of PMMA/TMD/Au;
(2) placing the 3-layer composite of PMMA/TMD/Au in an etching solution of potassium iodide and iodine (KI₂/I₂) to remove Au thereby forming a 2-layer composite of PMMA/TMD;
(3) transferring the 2-layer composite of PMMA/TMD on the substrate of SiO₂/Si or the TEM copper grid; and
(4) removing the PMMA by acetone.

According to embodiments of the present disclosure, the film of low-symmetry 2D TMD formed by the present method has about 98% of a unidirectional ratio of triangular-shaped 2D TMD. In some preferred embodiments of the present disclosure, the film of high-symmetry 2D TMD has about 98% of a unidirectional ratio of triangular-shaped ReS₂. In other embodiments of the present disclosure, the film of low-symmetry 2D TMD has about 98% of a unidirectional ratio of triangular-shaped ReS₂.

Other and further embodiments of the present disclosure are described in more detail below.

### BRIEF DESCRIPTION OF THE DRAWINGS

The disclosure will become more fully understood from the detailed description and the drawings given below for illustration only, and thus does not limit the disclosure, wherein:

FIG. 1A is a flowchart depicting steps for performing the present method 100 in accordance with preferred embodiment of the present disclosure;

FIG. 1B is a flowchart depicting steps for producing the gold foil with Au (111) domain in the method 100 of FIG. 1A;

FIG. 1C a flowchart depicting steps for transferring the film of low-symmetry 2D TMD produced in the method 100 of FIG. 1A;

FIG. 2A is a schematic diagram depicting centimeter-scale Au (111) domain preparation by contact-free method and aligned ReS₂ grown on Au (111) domain in accordance with one embodiment of the present disclosure;

FIG. 2B is a representative EBSD inverse pole figure map for gold foil after annealing in accordance with one embodiment of the present disclosure;

FIG. 2C are false-colored SEM images of aligned ReS₂ growth evolution from flake to continuous film with increasing amounts of precursors in accordance with one embodiment of the present disclosure;

FIG. 2D is the Polarized 70° OM image for transferred ReS₂ full film on SiO₂/Si in accordance with one embodiment of the present disclosure;

FIG. 2E is Raman spectrum for ReS₂ grown on Au (111) surface and transferred ReS₂ on SiO₂/Si in accordance with one embodiment of the present disclosure;

FIG. 2F is the AFM topography for aligned ReS₂ grown on Au (111) domain, in which one edge of ReS₂ is parallel to gold step. Inset image: corresponding phase image;

FIG. 2G is the cross-sectional HAADF-STEM for aligned ReS₂/Au (111) step structure in accordance with one embodiment of the present disclosure;

FIG. 2H is a schematic illustration of epitaxy growth of aligned ReS₂ on Au (111) in accordance with one preferred embodiment of the present disclosure;

FIG. 3A is a schematic diagram of ReS₂ orientation changes accompanied by increasing temperature in accordance with one embodiment of the present disclosure;

FIG. 3B is the false-colored SEM image for showing ReS₂ orientation evolution with the increase of growth temperature in accordance with one embodiment of the present disclosure;

FIG. 3C(i)-3C(ii) is the cross-sectional HAADF-STEM image for step structure of 0°-oriented FIG. 3C(ii) and 0° mirror-oriented FIG. 3C(i) ReS₂ in accordance with one embodiment of the present disclosure;

FIG. 3D(i)-3D(ii) is the cross-sectional BF-STEM image corresponding to FIG. 3C(i)-3C(ii);

FIG. 3E is a schematic diagram for atomic model of top view of 0°-oriented and 0° mirror oriented ReS₂, and magnified gold steps A and B structures in accordance with one embodiment of the present disclosure;

FIG. 3F is a schematic diagram for atomic model of cross-sectional view of 0°-oriented and 0° mirror-oriented ReS₂ in accordance with one embodiment of the present disclosure; and

FIG. 3G depicts the relative binding energy difference for ReS₂ nucleating at gold step edges A and B in accordance with one embodiment of the present disclosure.

### DETAILED DESCRIPTION

Detailed descriptions and technical contents of the present disclosure are illustrated below in conjunction with the accompanying drawings. However, it is to be understood that the descriptions and the accompanying drawings disclosed herein are merely illustrative and exemplary and not intended to limit the scope of the present disclosure.

### 1. Definition

The term “low-symmetry 2D TMD” as used herein refers to a class of 2D TMD material that exhibits in-plane anisotropy and distorted 1T structure. According to embodiments of the present disclosure, the low-symmetry 2D TMD refers to, 1T′-ReS₂ or 1T'-ReSe₂.

### 2. The Present Method

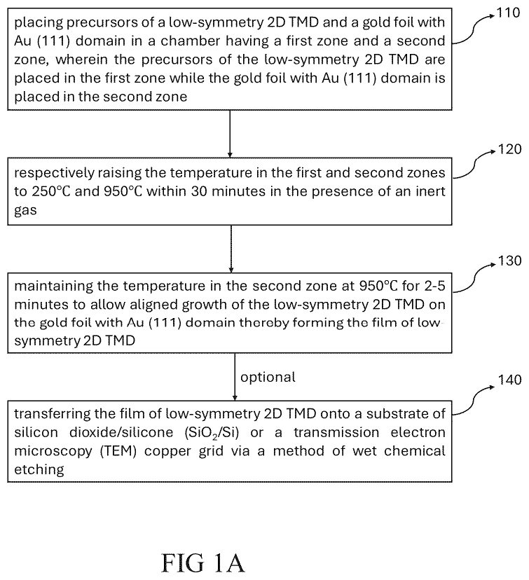

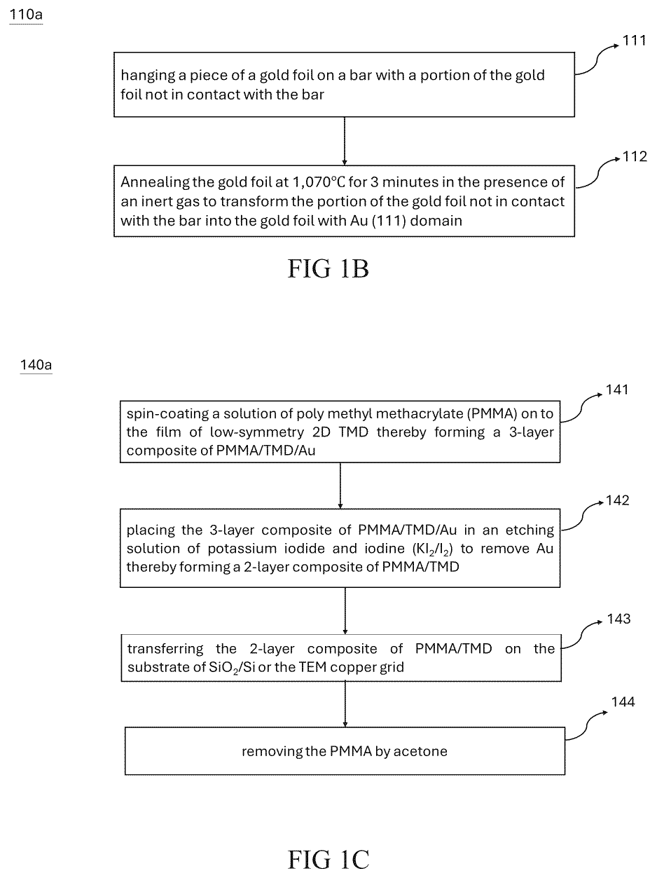

The present disclosure aims at providing a method of producing a film of low-symmetry 2D transition metal dichalcogenide (TMD). Reference is made to FIG. 1A, which is a flowchart depicting steps for performing the present method 100. The method 100 is performed in a 2-zone chamber, such as a chemical vapor deposition (CVD) chamber having first and second zones. The method 100 commences by placing precursors of a low-symmetry 2D TMD (e.g., precursors of ReS₂) in the first zone and the gold foil with Au (111) domain in the second zone (step 110).

Depending on the TMD intended to form, suitable precursors are selected and placed in the first zone of the 2-zone CVD chamber. In some embodiments, elemental sulfur(S) and ammonium perrhenate (NH₄ReO₄) for the synthesis of ReS₂ are placed in the first zone. In other embodiments, elemental selenium (Se) and ammonium perrhenate (NH₄ReO₄) for the synthesis of ReSe₂ are placed in the first zone.

According to embodiments of the present disclosure, the gold foil with Au (111) domain i produced by a contact-free method. Reference is made to the flowchart for the contact-free method 110a depicted in FIG. 1B. In the method 110a, a piece of gold foil (i.e., gold foil with Au (110) domain) is hung on a bar (e.g., quartz bar) in the single-zone CVD chamber, leaving a portion of the gold foil hanging freely or not in contact with the bar (step 111). The temperature in the single-zone CVD chamber is raised to an anneal temperature, and the gold foil is annealed at 1,070° C. for 3 minutes in the presence of an inert gas to transform the portion of the gold foil not in contact with the bar into the gold foil with Au (111) domain (Step 112). Examples of inert gas suitable for use in step 112 include, but are not limited to, argon, helium, nitrogen, etc. Preferably, step 112 is conducted in the presence of 100 sccm Ar gas. According to preferred embodiments of the present disclosure,

Returning to the present method 100, after step 110, the temperature in the first zone of the 2-zone CVD chamber is raised to 250° C., while the temperature in the second zone of the 2-zone CVD chamber is raised to 950° C. within 30 minutes in the presence of an inert gas (step 120). Examples of inert gas suitable for use in step 120 include, but are not limited to, argon, helium, nitrogen, etc. Preferably, step 120 is conducted in the presence of 150 sccm argon gas. Once the temperature in the second zone reaches 950° C., it is maintained for 2-5 minutes to allow aligned growth of the low-symmetry 2D TMD on the gold foil with Au (111) domain thereby forming the film of low-symmetry 2D TMD (step 130). According to some embodiments of the present disclosure, the film of low-symmetry 2D TMD thus produced is a film of low-symmetry 2D ReS₂. According to other embodiments of the present disclosure, the film of low-symmetry 2D TMD thus produced is a film of low-symmetry 2D TMD is a film of low-symmetry 2D ReS₂.

Alternatively or in addition, the present method 100 further includes a step of transferring the film of low-symmetry 2D TMD onto a substrate of silicon dioxide/silicone (SiO₂/Si) or a transmission electron microscopy (TEM) copper (Cu) grid via a method of wet chemical etching (Step 140). Reference is made to FIG. 1C, which is a flowchart depicting steps of the wet chemical etching method 140a. First, a solution of poly methyl methacrylate (PMMA) is spin coated on to the film of low-symmetry 2D TMD to form a 3-layer composite of PMMA/TMD/Au (step 141). Then, the 3-layer composite of PMMA/TMD/Au in immersed in an etching solution of potassium iodide and iodine (KI₂/I₂) to remove Au and a 2-layer composite of PMMA/TMD is formed (Step 142). The 2-layer composite of PMMA/TMD is then transferred on to the substrate of SiO₂/Si or the TEM copper grid (step 143); and the PMMA of the 2-layer composite of PMMA/TMD is removed by acetone (step 144). In some embodiments, the 2-layer composite of PMMA/TMD is transferred to the substrate of SiO₂/Si. In other embodiments, the 2-layer composite of PMMA/TMD is transferred to the TEM copper grid.

According to embodiments of the present disclosure, the film of low-symmetry 2D TMD is transferred to the substrate of SiO₂/Si and has a unidirectional ratio of triangular-shaped ReS₂ of about 98%.

The present invention will now be described more specifically with reference to the following embodiments, which are provided for the purpose of demonstration rather than limitation. While they are typically of those that might be used, other procedures, methodologies, or techniques known to those skilled in the art may alternatively be used.

### EXAMPLES

### Material and Methods

### Preparation of Centimeter Scale Size Au (111) Domain

A piece of commercial polycrystal gold foil (1.5 cm×1 cm, ˜99.985% purity, 25 μm in thickness) were hanged on a quartz bar of a homemade quartz holder, then the entire holder was loaded into a single zone CVD chamber and annealed at 1,070° C. for 3 minutes under 100 sccm Ar gas. The contact-free area of gold foil would transform into Au (111) domain at high temperature due to minimization of surface energy.

### CVD Growth of Aligned ReS₂ on Au (111)

Aligned ReS₂ were synthesized by using a two-zone CVD. A piece of annealed gold foil (1.5 cm×1 cm) having Au (111) domain was placed on a quartz holder and loaded into the center of downstream CVD chamber. 100 mg sulfur and 50 mg ammonium perrhenate (NH₄ReO₄) powders serving as precursors were placed at the center of the upstream CVD chamber and located between sulfur and gold substrate, respectively. Upstream CVD was heated to 250° C. while downstream CVD was heated to 950° C. within 30 minutes under 150 sccm Ar gas, and maintaining at growth temperature for 2˜5 min. When the chamber cooled down to room temperature, aligned ReS₂ film were obtained.

### Transfer of Aligned Res₂

Aligned ReS₂ were transferred from gold to SiO₂/Si substrate or TEM Cu grid by wet chemical etching method. A poly(methyl methacrylate) (PMMA) film coated ReS₂/Au was put into the Au etchant solution (KI₂-I₂ solution), and after Au were totally etched away, PMMA/ReS₂ were transferred to DI water for 3 times to remove residual etchant. Finally, a clean PMMA/ReS₂ was transferred to the target substrate and PMMA were removed by acetone.

### Characterization of Materials

Synthesized aligned ReS₂ morphology was observed by OM (ZEISS Imager.A2m) under bright filed, and polarization mode, and by SEM (Quattro S, Thermo Scientific). The topography phase and CAFM of ReS₂ were measured by atomic force microscope (AFM5300E, HITACHI). Raman spectra were produced by confocal Raman microscope (Renishaw, UK) using the excitation wavelength of 633 nm and 514 nm (for polarized Raman measurement). Cross-sectional lamella of ReS₂/Au were prepared by focus ion beam (Helios 5 CX Dual Beam FIB, Thermo Scientific). The transmission electron microscope (JEOL, JEM-2100F; acceleration voltage, 200 kV), and double spherical aberration-corrected transmission electron microscope (Thermo Fisher Spectra 300, operated at 300 kV and 80 kV) were used to evaluate SAED pattern, cross-sectional ReS₂/Au (111) lamella and transferred ReS₂ on Cu grid. The elemental composition and chemical states were recorded by XPS spectra using a SPECS Phoibos 150 hemispherical electron energy analyzer with a base vacuum lower than 10⁻⁹ mbar. EBSD data were collected by Nordlys Max3 EBSD Detector (Oxford Instruments).

### Density Functional Theory (DFT) Calculation

To investigate the geometries and electronic properties of ReS₂—Au materials, spin-polarized density functional theory (DFT) calculations were conducted using the Vienna ab initio Simulation Package (VASP) program package (Kresse et al., Phys. Rev. B (1996) 54(16), 11169-11186; Kresse and Furthmüller, Cpmput. Mater. Sci. (1996) 6(1), 15-50) with the projector augmented wave (PAW) (Blochl, P. E., Phys. Rev. B Condens. Matter (1994) 50(24), 17953-17979). The exchange-correlation interactions were described using the Perdew, Burke, and Ernzernhof (PBE) functional with the generalized gradient approximation (GGA) (Perdew et al., Phys. Rev. Lett. (1996) 77(18), 3865-3868). The kinetic energy cutoff for the plane-wave basis set was set to 450 eV, and the distance of the vacuum layer was greater than 20 Å to prevent interlayer interactions. To correct for van der Waals interactions on the surface, the DFT-D3 scheme of Grimme (Grimme et al., J. Chem. Phys. (2010), 132(15), 154104) was applied. The electronic SCF tolerance was set to 10⁻⁴ eV. Fully relaxed geometries and lattice constants were obtained by optimizing all atomic positions until the Hellmann-Feynman forces were less than 0.02 eV/Å. The structural optimizations used a gamma-centred Monkhorst-Pack scheme (Monkhorst and Pack, Phys. Rev. B (1976) 13(12), 5188-5192) with k-point samplings of 3×3×1. The bottom layer of gold atoms was fixed to simulate the Au substrate.

### Example 1: Formation of Highly Oriented Crystal Growth of ReS₂ Film

### 1.1 Growth of Aligned ReS₂ Film on Au (111) Domain

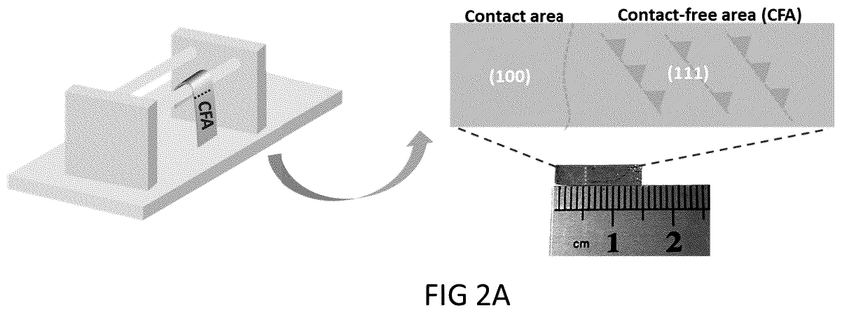

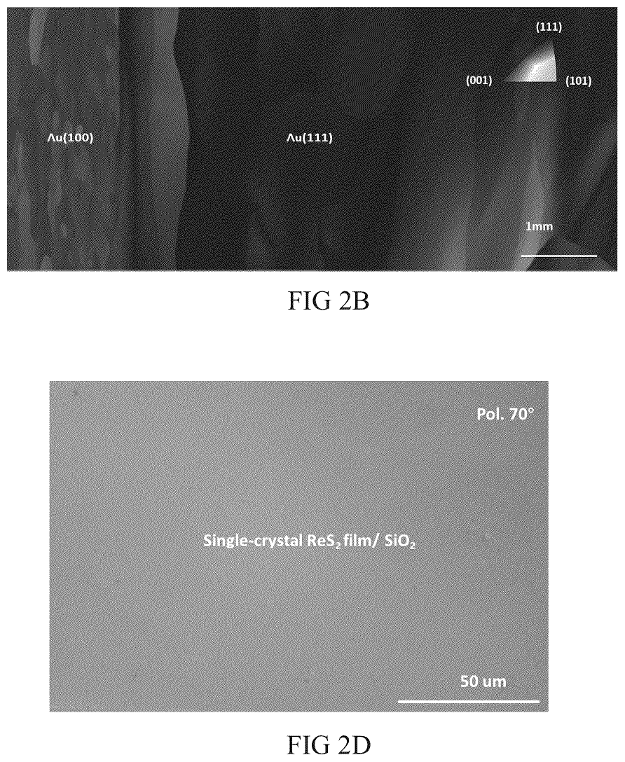

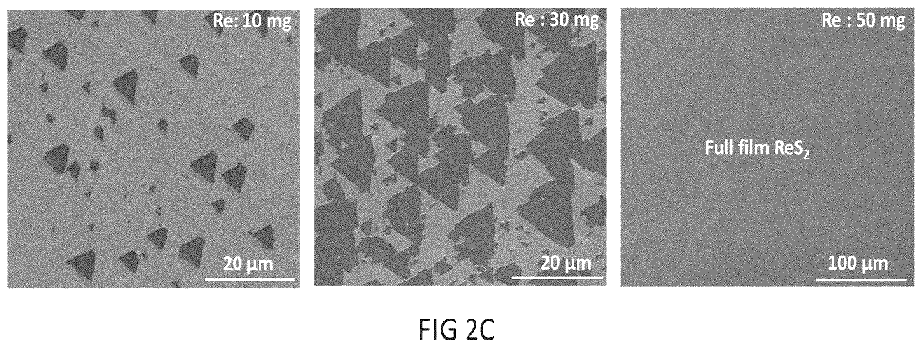

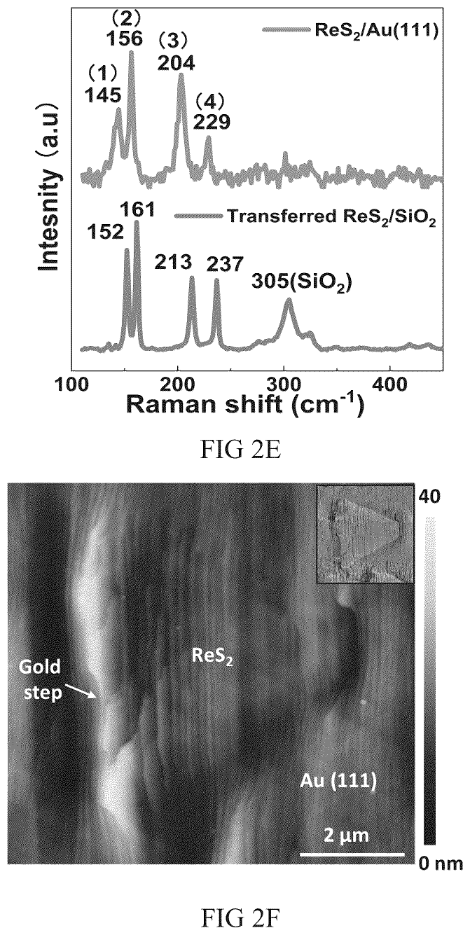

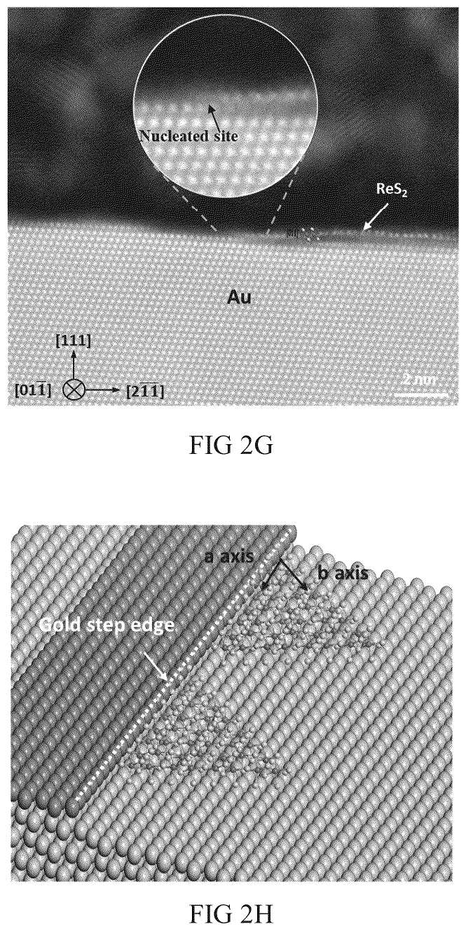

In this example, large Au (111) domain was prepared from commercial polycrystalline Au foil by using contact-free annealing method in an argon atmosphere at a high temperature in accordance with procedures described in “Material and method” section. Briefly, the gold foil was hanged on a quartz holder, creating a contact-free area (CFA). At annealing process, under a high temperature close to gold melting point, CFA of gold was spontaneously transformed to Au (111) domain, which was driven by factor of minimization of surface energy, while contact area of gold was transformed to Au (100) (FIG. 2A). The thus produced Au (111) domain could reach to 10 mm×5 mm (FIG. 2A) and representative electron backscatter diffraction (EBSD) data in the normal direction for annealed Au foil confirm the formation of centimeter-scale size Au (111) domain (FIG. 2B).

Monolayer unidirectional triangular ReS₂ was subsequently grown on Au (111) domain later by using CVD method at 950° growth temperature under atmospheric pressure. Sulfur and ammonium perrhenate (NH₄ReO₄) powders were used as precursors for the growth. By increasing the amounts of precursors in the growth experiment, well-aligned ReS₂ flake sample merged and formed a continuous film on the Au (111) domain, which was confirmed by scanning electron microscope (SEM) image (FIG. 2C).

Angle-resolved polarized optical microscopy (ARPOM) has been proved to be an effective technique for distinguishing different ReS₂ subdomains and grain boundaries based on optical contrast at various polarization angles, therefore ARPOM was used to determine whether ReS₂ is polycrystalline or not. Among polarization angles ranging from 0° to 180°, an angle of approximately 70° could provide superior optical contrast for ReS₂ domain. FIG. 2D is a photograph of a polarized 70° optical microscope image for a ReS₂ film on SiO₂/Si substrate, the ReS₂ film was transferred from Au (111) surface via gold etching method according to procedures described in “Material and methods” section. Additional polarized OM images of the film, taken at angles from 0° to 180° under higher magnification, and the atomic force microscope (AFM) phase image of this film exhibited no clear domain contrast, reflecting highly oriented crystal property of the film (data not shown). By contrast, a grown ReS₂ film transferred from other Au surface (e.g., Au (100)) exhibited clear domain contrast, demonstrating Au (111) was a superior surface for preparing highly oriented crystal of ReS₂.

The Raman spectra (FIG. 2E) and X-ray photoemission spectroscopy (XPS) for ReS₂/Au (111) further confirmed the formation of ReS₂ on Au (111) domain. For Raman spectra, compared with ReS₂ on SiO₂ transferred from Au (111), it is worth noting that Raman peaks for pristine ReS₂ grown on Au (111) surface has a strong red shift with peaks 1, 2, 3 and 4 shifting left by approximately 7 cm⁻¹, 5 cm⁻¹, 9 cm⁻¹ and 8 cm⁻¹, respectively, which might arise from the tensile strain applied from gold substrate. The XPS characteristic peaks at ˜42.3 eV and ˜44.7 eV correspond to Re 4f_{7/2} and 4f_{5/2}, while ˜162.7 eV and ˜163.8 eV correspond to S 2p_{3/2} and S 2p_{1/2}, respectively. The atomic force microscope (AFM) topography height profile for ReS₂ transferred from Au (111) to SiO₂/Si substrate indicated a thickness of approximately 0.6 nm, confirming the monolayer nature of ReS₂. The observed roughness of the as-transferred ReS₂ was primarily attributed to wrinkles induced during the transfer process, a phenomenon commonly encountered in the transfer of other 2D materials as well.

To further confirm the consistency of crystal orientation of ReS₂ film on Au (111) surface, transmission electron microscopy (TEM) selected area electron diffraction (SAED) for a transferred ReS₂ film on TEM copper grid at 16 randomly selected positions was measured. The SAED pattern indicated 12 positions exhibited same crystal orientation, and high-magnification scanning transmission electron microscopy (STEM) atomic image collected from one of these positions confirmed the clear single crystal nature (data not shown), although remaining 4 positions exhibited different lattice orientation, which should originate from partially inevitable lattice reconstruction during cooling stage of sample's CVD growth. Additionally, for a transferred ReS₂ film on SiO₂/Si substrate, polarized Raman intensity mapping for peak 213 cm⁻¹ under a polarization angle of 170° was also performed, where its peak intensity reached maximum intensity according to polar plot of angle-dependent Raman intensity result (data not shown). The uniform color contrast in mapping image further confirmed the film was formed by highly oriented ReS₂ crystals.

### 1.2 Gold Step Edge Guided Growth

AFM topography and phase image of as-grown ReS₂ on gold showed that one edge of ReS₂ was parallel to the step of Au (111) surface (FIG. 2F). To examine the gold step structure and ReS₂/Au (111) interface, a cross-sectional ReS₂/Au lamella was prepared using focused ion beam technique (FIB), with the cutting direction perpendicular to one edge of ReS₂ and the step edge of gold. High-angle angular dark-field scanning transmission electron microscopy (HAADF-STEM) was used to investigate the atomic structure of the prepared lamella. FIG. 2G is the cross-sectional HAADF-STEM image for ReS₂/Au viewed along Au [011̅] direction. Those bright dots representing ReS₂ correspond to Re atoms, and inset magnified image illustrated the leftmost Re atom was on the right side of topmost gold atom. The observation demonstrated that ReS₂ nucleates on the side of atomic-height gold step edge along [011̅] direction with its a axis (Re-chain direction) paralleled to the step edge. The schematic diagram of ReS₂ epitaxy growth is shown in FIG. 2H. Aligned ReS₂ growth on Au (111) surface followed a step-edge-guided growth mechanism, in which step edge breaks six-fold symmetry of Au (111) substrate and provides a preferred nucleation site along Au [011̅] direction, facilitating predominant unidirectional growth.

### 1.3 Growth Temperature

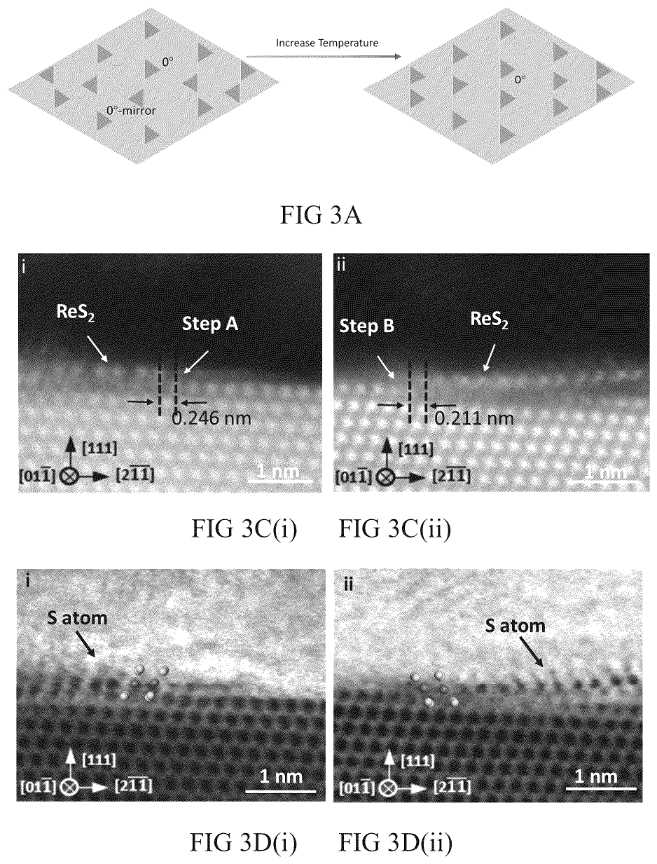

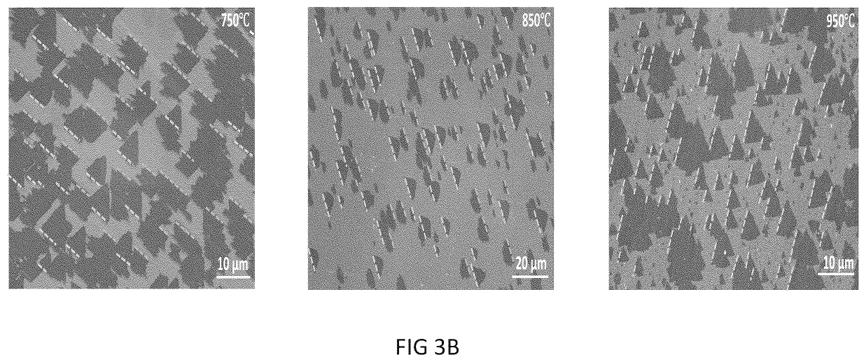

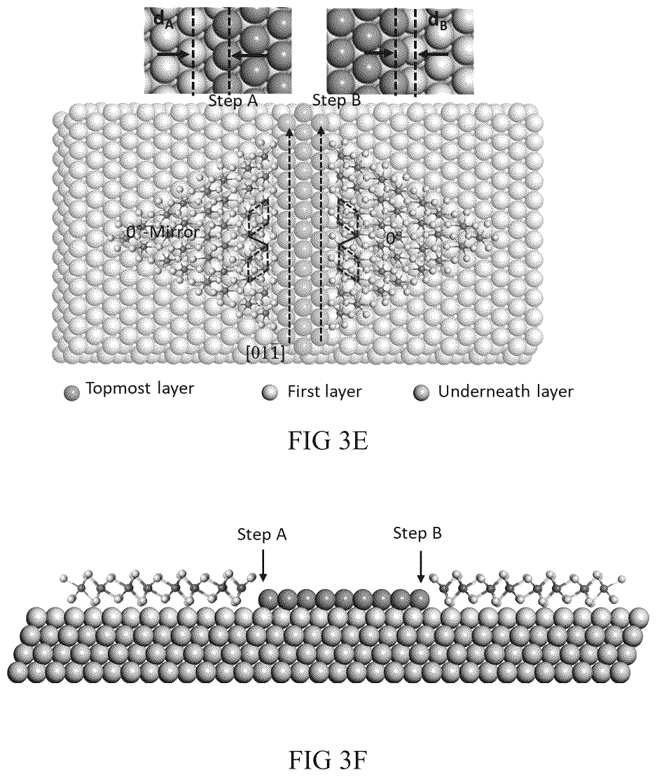

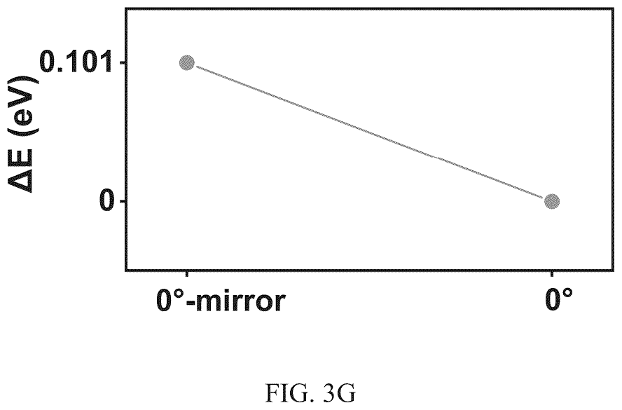

In this example, the growth temperature in controlling ReS₂ preferred growth direction was investigated, and results are illustrated in FIGS. 3A to 3G.

It was found that at low growth temperature, such as 750° C. and 850° C., samples showed both 0°-oriented and 0° mirror-oriented growth direction, and proportion ratio of 0°-oriented was around 50% (FIGS. 3A and 3B). Additionally, morphology of ReS₂ was not very regular triangular shape at low growth temperature. When the growth temperature increased to a higher growth temperature, 950° C., unidirectional ratio of triangular-shaped ReS₂ reached approximately 98.2%, according to statistical analysis of ReS₂ at different location in a large-scale Au (111) area (data not shown).

To better understand ReS₂ nucleation and orientation selectivity, the nucleation site structure of ReS₂ toward 0°/0° mirror-oriented was studied by cross-sectional STEM (FIG. 3C(i)-3C(ii) and 3D(i)-3D(ii)). It was noticed that sulfur atom positioned on 0° and 0° mirror-oriented ReS₂ exhibited a mirror-symmetry relationship, as indicated by the bright field (BF)-STEM image (FIG. 3D(i)-3D(ii)). At the same time, combing with top view of STEM image for edge structure of transferred 0° and 0°-mirror oriented ReS₂ on TEM grid (data not shown), two oriented ReS₂ have the same a-axis (Re-chain) direction while the b-axis was opposite to each other. Atomic model of top view and cross-sectional view for two configurations of ReS₂ are shown in FIGS. 3E and 3F. Here, gold step edges with 0° mirror and 0°-oriented ReS₂ were respectively docked as steps A and B. FIG. 3C(i)-3C(ii) shows the distance between gold step B and its docked Re atom was 0.211 nm, while the distance at step A side was 0.246 nm. FIG. 3E shows the distance between gold atom at step edge and its closest gold column at the first layer differed for these two configurations (d_{A}>d_{B}). Based on the above structure analysis, density functional theory (DFT) calculation was conducted to determine the energy differences for two configurations. As a result, the binding energy for ReS₂ nucleating at step B was lower and had a 0.101 eV difference from step A, which made ReS₂ more likely to nucleate at step edge B (FIG. 3G). Furthermore, increasing the growth temperature should amplify the nucleation rate differences between gold step A and step B, closer to more thermodynamically growth conditions. Both factors collectively made ReS₂ exhibited unidirectional growth.

Additionally, we measured Re—Au distance (d₁) and S—Au distance (d₂) for ReS₂ grown Au surface (111), (110) and (100), respectively according to captured cross-sectional BF-STEM image (data not shown). Measured distance data d₁ ranged from approximately 0.410 to 0.439 nm, which was shorter than reported distances between gold and other TMDs material. Meanwhile, the distances d₂ ranged from 0.211 to 0.246 nm, closely aligning with values observed in CVD-grown aligned MoS₂ on gold. The analysis indicated a strong interaction between the grown ReS₂ and gold substrate, likely contributing to the alignment growth of ReS₂ on Au (111).

In summary, the data above demonstrates the production of centimeter-scale Au (111) surface by contact-free annealing method and growth of highly oriented crystal of the low-symmetry TMDs material, ReS₂, with a triangular shape and large area film on high-symmetry Au (111) surface. The findings indicate that, beyond step-edge-guided growth mechanism, growth temperature also plays a crucial role in controlling the preferred growth direction of ReS_{2.} The study provides valuable insights into the aligned growth of low-symmetry 2D materials, paving a way for its large-scale single-crystal film growth and integration.

It will be understood that the above description of embodiments is given by way of example only and that various modifications may be made by those with ordinary skill in the art. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of the present disclosure.

What is claimed is:

1. A method of producing a film of low-symmetry two-dimensional (2D) transition metal dichalcogenide (TMD), the method comprises:
(a) placing precursors of a low-symmetry 2D TMD and a gold foil with Au (111) domain in a chamber having a first zone and a second zone, wherein the precursors of the low-symmetry 2D TMD are placed in the first zone while the gold foil with Au (111) domain is placed in the second zone;
(b) respectively raising the temperature in the first and second zones to 250° C. and 950° C. within 30 minutes in the presence of an inert gas; and
(c) maintaining the temperature in the second zone at 950° C. for 2-5 minutes to allow aligned growth of the low-symmetry 2D TMD on the gold foil with Au (111) domain thereby forming the film of low-symmetry 2D TMD;
wherein,
the film of low-symmetry 2D TMD has about 98% of a unidirectional ratio of triangular-shaped 2D TMD.

2. The method of claim 1, wherein in step (a), the gold foil with Au (111) domain is produced by a method comprising:
(i) hanging a gold foil on a bar with a portion of the gold foil not in contact with the bar; and
(ii) annealing the gold foil at 1,070° C. for 3 minutes in the presence of an inert gas to transform the portion of the gold foil not in contact with the bar into the gold foil with Au (111) domain;
wherein, the Au (111) domain is in centimeter-scale.

3. The method of claim 1, wherein in step (a) the precursors of the low-symmetry 2D TMD are elemental sulfur and ammonium perrhenate (NH₄ReO₄) or elemental selenium (Se) and ammonium perrhenate (NH₄ReO₄).

4. The method of claim 3, wherein the inert gas in step (b) or step (ii) is helium, argon, or nitrogen.

5. The method of claim 1, wherein in step (c), the film of low-symmetry 2D TMD is a film of low-symmetry 2D ReS₂ or a film of low-symmetry 2D ReSe₂.

6. The method of claim 1, further comprising transferring the film of low-symmetry 2D TMD onto a substrate of silicon dioxide/silicone (SiO₂/Si) or a transmission electron microscopy (TEM) copper grid via a method of wet chemical etching.

7. The method of claim 6, wherein the method of wet chemical etching comprises steps of:
(1) spin-coating a solution of poly methyl methacrylate (PMMA) on to the film of low-symmetry 2D TMD thereby forming a 3-layer composite of PMMA/TMD/Au;
(2) placing the 3-layer composite of PMMA/TMD/Au in an etching solution of potassium iodide and iodine (KI₂/I₂) to remove Au thereby forming a 2-layer composite of PMMA/TMD;
(3) transferring the 2-layer composite of PMMA/TMD on the substrate of SiO₂/Si or the TEM copper grid; and
(4) removing the PMMA by acetone.

8. The method of claim 7, wherein in step (a), the precursors of the low-symmetry 2D TMD are elemental sulfur and ammonium perrhenate (NH₄ReO₄) or elemental selenium (Se) and ammonium perrhenate (NH₄ReO₄).

9. The method of claim 8, wherein the inert gas in step (b) or step (ii) is helium, argon, or nitrogen.

10. The method of claim 9, wherein in step (c), the film of low-symmetry 2D TMD is a film of low-symmetry 2D ReS₂ or a film of low-symmetry 2D ReSe₂.
